(19) United States
(12) Patent Application Publication
(10) Pub. No.: US 2006/0214308 A1
(43) Pub. Date: Sep. 28, 2006

(54) Flip-chip semiconductor package and method for fabricating the same

(75) Inventors: Kuo-Hua Yu, Taichung (TW); Chin-Te Chen, Taichung (TW); Han-Ping Pu, Taipei Hsien (TW); Cheng-Hsu Hsiao, Taichung Hsien (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/347,735

(22) Filed: Feb. 2, 2006

(30) Foreign Application Priority Data
Mar. 23, 2005 (TW) 094108915

(51) Int. Cl. H01L 23/48

(52) U.S. Cl. 257/778

(57) ABSTRACT

A flip-chip semiconductor package and a method for fabricating the same are proposed. A flux is formed on surfaces of solder bumps mounted on an active surface of a semiconductor chip, wherein the acid number of the flux is greater than 20 and the viscosity of the flux is greater than 40. When the chip is electrically connected to a lead frame via the solder bumps by a reflowing process, the flux allows the chip to be effectively fixed to the lead frame and makes the solder bumps not easily wetted to the lead frame during the reflowing process, so as to prevent over-collapsing of the solder bumps.

### FIELD OF THE INVENTION

The present invention relates to flip-chip semiconductor packages and methods for fabricating the same, and more particularly, to a flip-chip lead-frame-based semiconductor package and a method for fabricating the semiconductor package.

### BACKGROUND OF THE INVENTION

Conventional lead-frame-based semiconductor package uses a lead frame as a carrier where a semiconductor chip is mounted in a manner that an inactive surface of the chip is attached to a die pad of the lead frame and an active surface of the chip is electrically connected to leads of the lead frame via bonding wires. The semiconductor package further includes an encapsulant for encapsulating the chip, the bonding wires and the lead frame. However, the use of the bonding wires makes a signal transmission path relatively long such that signals being transmitted through the bonding wires usually become weakened in the semiconductor package. Further, loops of the bonding wires are easily subject to shifting or sagging in response to mold impact during a molding process of forming the encapsulant, thereby resulting in undesirable contact between adjacent bonding wires and causing short circuit. Moreover, the thickness of the semiconductor package is hardly reduced due to the presence of the bonding wires having a certain height of loops.

Accordingly, a flip-chip semiconductor package using a lead frame has been proposed. Referring to FIG. 1, the flip-chip semiconductor package includes a semiconductor chip 11 having its active surface 111 mounted on the lead frame 14 and a plurality of solder bumps 12 formed on the active surface 111, such that the chip 11 is electrically connected to leads 141 or a die pad (not shown) of the lead frame 14 via the solder bumps 12. By this arrangement, no bonding wire is required for the electrical connection, such that the quality of electrical connection can be improved and the thickness of the semiconductor package can be effectively reduced.

The flip-chip lead-frame-based semiconductor package is further advantageous in that the solder bumps for electrically connecting the chip to the leads can be formed on the chip by a self-alignment technique, which is more time- and labor-effective as compared to the prior art using the bonding wires that are fabricated one by one.

However, the above flip-chip lead-frame-based semiconductor package encounters a drawback that, as shown in FIG. 1B, the solder bumps 12 would collapse during a reflowing process of bonding the solder bumps 12 to the leads 141. Since the leads 141 are made of copper and have good wettability, the solder bumps 12 at a certain high temperature melt and collapse to be wetted to the leads 141, and the collapse 16 of the solder bumps 12 not only covers predetermined areas of the leads 141 but also continues to reach unintended areas of the leads 141. The over collapse 16 of the solder bumps 12 may cause a bridging effect between adjacent solder bumps 12, resulting in electrical failure. Further, the solder bumps 12 may be over deformed due to the collapse 16 and affect performance of subsequent fabrication processes.

Accordingly, U.S. Pat. No. 6,507,120 has disclosed a flip-chip quad flat non-leaded (FC-QFN) semiconductor package. As shown in FIG. 2, the semiconductor package 200 includes a lead frame having a plurality of leads 202; a semiconductor chip 210 attached and electrically connected to the leads 202 via a plurality of solder bumps 218; and an encapsulant 224 for encapsulating the chip 210, the solder bumps 218 and an upper surface of the lead frame. A solder mask layer 220 is applied on the leads 202 and is formed with openings at positions corresponding to the solder bumps 218, such that the solder bumps 218 can be prevented from collapsing to other unintended areas on the leads 202 during the reflowing process by virtue of the solder mask layer 220.

However, forming the additional solder mask layer on the lead frame and patterning the solder mask layer by exposure, development and so on to form the openings thereof undesirably cause difficulty in fabricating the lead frame and increase the cost of the lead frame.

U.S. Pat. No. 6,482,680 has disclosed a method of forming a tin layer by printing or electroplating on a copper-made lead frame at positions predetermined for bonding solder bumps formed on a chip in order to effectively bond the solder bumps to the lead frame via the tin layer. However, this method does not solve the over-collapsing problem but increases the fabrication cost.

Therefore, the problem to be solved here is to provide a flip-chip lead-frame-based semiconductor package, which can be fabricated by simplified processes without effectively increasing the cost, and can prevent over-collapsing of solder bumps for electrically connecting a chip to leads, so as to ensure the reliability of the semiconductor package, without having to in advance apply any printing process to the lead frame.

### SUMMARY OF THE INVENTION

In light of the foregoing drawbacks in the prior art, an objective of the present invention is to provide a flip-chip semiconductor package and a method for fabricating the same, which can prevent over-collapsing of a solder material used in the flip-chip technology, thereby ensuring the reliability of the semiconductor package.

Another objective of the present invention is to provide a flip-chip semiconductor package and a method for fabricating the same, which can fabricate the semiconductor package by simplified processes without effectively increasing the cost, and can prevent over-collapsing of solder bumps for electrically connecting a flip chip to a lead frame.

A further objective of the present invention is to provide a flip-chip semiconductor package and a method for fabricating the same, without having to in advance form a tin layer on a lead frame by printing or electroplating, thereby reducing the fabrication cost.

In order to achieve the above and other objectives, the present invention proposes a flip-chip semiconductor package comprising: a lead frame; at least one semiconductor chip having an active surface and an inactive surface, with a plurality of solder bumps being formed on the active surface, wherein the chip is electrically connected to the lead frame via the solder bumps that are subjected to reflowing; and an encapsulant for encapsulating the chip, the solder bumps and a portion of the lead frame. Before the chip is attached to the lead frame via the solder bumps by the reflowing process, a flux is applied on surfaces of the solder bumps, wherein the acid number of the flux is greater than 20 and the viscosity of the flux is greater than 40. The acid number is obtained by a test performed on the flux in accordance with Method 2.3.13 of IPC-TM-650, and the viscosity is obtained by a test performed on the flux at 10 rpm and 25° C. using Malcom Viscometer. The lead frame comprises a plurality of leads where the solder bumps on the chip can be bonded. The lead frame further comprises a die pad where the solder bumps on the chip can also be bonded, such that the die pad may serve as an additional electrical connection contact such as grounding contact for the semiconductor package.

The above flip-chip semiconductor package can be fabricated by the steps comprising: applying a flux on surfaces of solder bumps formed on an active surface of a semiconductor chip, wherein the acid number of the flux is greater than 20 and the viscosity of the flux is greater than 40; electrically connecting the chip to a lead frame via the solder bumps by a reflowing process; forming an encapsulant for encapsulating the chip, the solder bumps and a portion of the lead frame. The flux allows the chip to be effectively fixed to the lead frame and makes the solder bumps not easily wetted to the lead frame during the reflowing process so as to prevent over-collapsing of the solder bumps.

Therefore, according to the flip-chip semiconductor package and the method for fabricating the same of the present invention, before attaching and electrically connecting a semiconductor chip to a lead frame via solder bumps by a reflowing process, a flux is formed on surfaces of the solder bumps, wherein the acid number of the flux is greater than 20 and the viscosity of the flux is greater than 40. The characteristics of the flux having the acid number greater than 20 and the viscosity greater than 40 allow the solder bumps to well melt and be effectively bonded to the lead frame, such that over-collapsing of the solder bumps can be prevented. Moreover, the fabrication method of the present invention utilizes simplified process as not having to in advance form a tin layer on the lead frame by printing or electroplating, thereby reducing the cost and improving the yield.

### BRIEF DESCRIPTION OF THE DRAWINGS

The present invention can be more fully understood by reading the following detailed description of the preferred embodiments, with reference made to the accompanying drawings, wherein:

FIG. 1A (PRIOR ART) is a cross-sectional view of a conventional flip-chip semiconductor package using a lead frame;

FIG. 1B (PRIOR ART) is a cross-sectional view showing over-collapsing of solder bumps during a reflowing process in the flip-chip semiconductor package of FIG. 1A;

FIG. 2 (PRIOR ART) is a cross-sectional view of a flip-chip quad flat non-leaded package disclosed in U.S. Pat. No. 6,507,120;

FIGS. 3A-3C are cross-sectional views of steps of a method for fabricating a flip-chip semiconductor package according to a preferred embodiment of the present invention; and

FIG. 4 is a cross-sectional view of a flip-chip semiconductor package according to another preferred embodiment of the present invention.

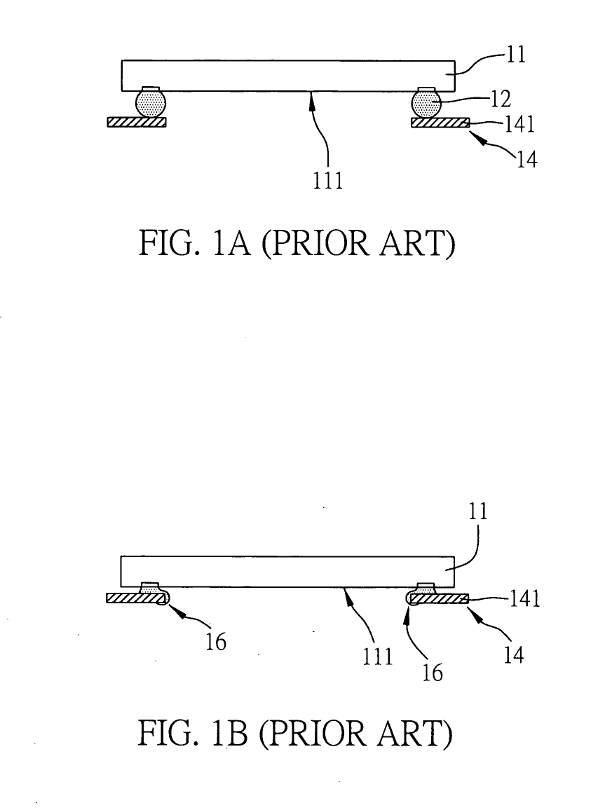

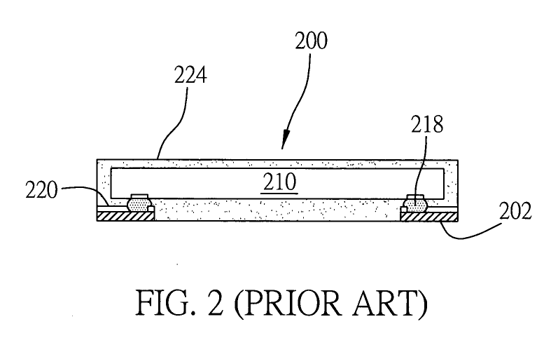

### DETAILED DESCRIPTION OF THE PREFERRED EMBODIMENTS

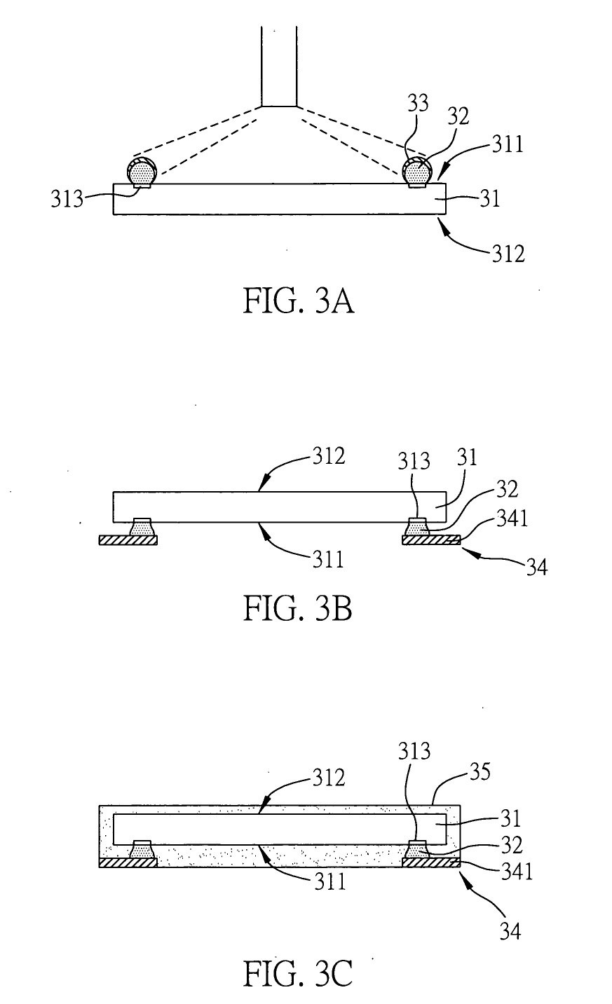

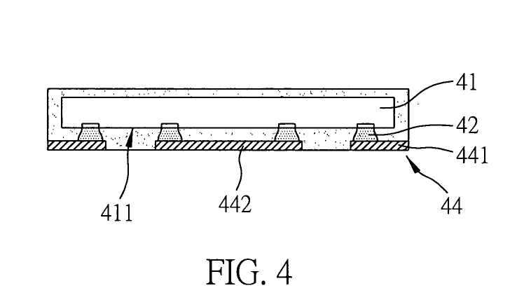

Preferred embodiments of a flip-chip semiconductor package and a method for fabricating the same proposed in the present invention are described as follows with reference to FIGS. 3A-3C and 4. The following embodiments illustrate, but are not limited to, a flip-chip quad flat non-leaded (FC-QFN) semiconductor package. The drawings are simplified schematic diagrams only showing components/elements directly relating to the present invention. It should be understood that the semiconductor package is not limited to the components/elements shown in the drawings, and the components/elements layout of the semiconductor package can be more complex in practice.

FIGS. 3A-3C show steps of a method for fabricating a flip-chip semiconductor package according to a preferred embodiment of the present invention.

Referring to FIG. 3A, a semiconductor chip 31 is provided, which has an active surface 311 and an opposed inactive surface 312. The active surface 311 is formed with a plurality of electrode pads 313 thereon, and solder bumps 32 are mounted on the electrode pads 313. The solder bumps 32 can be made of a lead-rich material or a lead-free material. A flux 33 is applied on surfaces of the solder bumps 32, wherein the acid number of the flux 33 is greater than 20 and the viscosity of the flux 33 is greater than 40. The acid number is obtained by a test performed on the flux 33 in accordance with Method 2.3.13 of IPC-TM-650, and the viscosity is obtained by a test performed on the flux 33 at 10 rpm and 25° C. using Malcom Viscometer. The flux 33 can be formed on the surfaces of the solder bumps 32 by dipping, printing or spraying, etc. The process of forming the flux 33 can be performed on the entire wafer or singulated chips mounted with solder bumps.

Referring to FIG. 3B, the chip 31 is electrically connected to a lead frame 34 via the solder bumps 32 by a reflowing process in a flip-chip manner. The lead frame 34 comprises a plurality of leads 341, and the solder bumps 32 on the active surface 311 of the chip 31 are bonded and electrically connected to the leads 341 of the lead frame 34. The chip 31 is fixed to the lead frame 34 due to the viscosity of the flux 33, and after the reflowing process, the flux 33 becomes hardened such that the solder bumps 32 when forming solder joints would not be easily wetted to the lead frame 34, thereby preventing over-collapsing of the solder bumps 32.

Referring to FIG. 3C, a molding process is carried out. The lead frame 34 mounted with the chip 31 and the solder bumps 32 is placed into a cavity of a mold (not shown), allowing lower surfaces of the leads 341 to come into contact with a bottom surface of the cavity of the mold. Then, a resin material such as epoxy resin is injected into the cavity of the mold to encapsulate the lead frame 34, the chip 31 and the solder bumps 32, and when the resin material is cured, an encapsulant 35 is formed. Then, the mold is removed such that the lower surfaces of the leads 341 are exposed from the encapsulant 35 and the semiconductor package of the present invention is completely fabricated. The exposed lower surfaces of the leads 341 may subsequently used for electrical connection with an external device (not shown).

By the above fabrication method, a flip-chip semiconductor package is provided in the present invention, comprising: a lead frame 34 having a plurality of leads 341; at least one semiconductor chip 31 having an active surface 311 and an inactive surface 312, wherein the active surface 311 of the chip 31 is electrically connected to the leads 341 via a plurality of solder bumps 32 by a reflowing process, and before attaching the chip 31 to the lead frame 34 via the solder bumps 32, a flux 33 is formed on surfaces of the solder bumps 32, with the acid number of the flux 33 being greater than 20 and the viscosity of the flux 33 being greater than 40; and an encapsulant 35 for encapsulating the chip 31, the solder bumps 32 and a portion of the lead frame 34.

Therefore, according to the flip-chip semiconductor package and the method for fabricating the same of the present invention, before attaching and electrically connecting a semiconductor chip to a lead frame via solder bumps by a reflowing process, a flux is applied on surfaces of the solder bumps, wherein the acid number of the flux is greater than 20 and the viscosity of the flux is greater than 40. The characteristics of the flux having the acid number greater than 20 and the viscosity greater than 40 allow the solder bumps to well melt and be effectively bonded to the lead frame, such that over-collapsing of the solder bumps can be prevented, especially for the lead-rich or lead-free solder bumps. Moreover, the fabrication method of the present invention utilizes simplified process as not having to in advance form a tin layer on the lead frame by printing or electroplating, thereby reducing the cost and improving the yield.

FIG. 4 shows a flip-chip semiconductor package according to another preferred embodiment of the present invention. As shown in FIG. 4, the semiconductor package of this embodiment is similar to that described in the foregoing embodiment, with a primary difference in that in this embodiment, a lead frame 44 further includes a die pad 442 in addition to leads 441. After a flux is applied on surfaces of solder bumps 42 formed on an active surface 411 of a semiconductor chip 41, the chip 41 can be attached and electrically connected to both the leads 441 and the die pad 442 via the solder bumps 42 by a reflowing process, such that the die pad 442 may serve as an additional electrical connection contact such as grounding contact for the semiconductor package.

The invention has been described using exemplary preferred embodiments. However, it is to be understood that the scope of the invention is not limited to the disclosed embodiments. On the contrary, it is intended to cover various modifications and similar arrangements. For example, during the fabrication method, a lead frame module plate comprising a plurality of lead frames can be used to simultaneously fabricate a plurality of semiconductor packages, and subsequently a singulation process is performed to form individual semiconductor packages. The scope of the claims, therefore, should be accorded the broadest interpretation so as to encompass all such modifications and similar arrangements.

What is claimed is:

1. A flip-chip semiconductor package, comprising:
a lead frame; and
at least one semiconductor chip having an active surface and an opposed inactive surface, with solder bumps being formed on the active surface, wherein the chip is electrically connected to the lead frame via the solder bumps that are subjected to reflowing;
wherein before the chip is electrically connected to the lead frame via the solder bumps, a flux is formed on surfaces of the solder bumps, with an acid number of the flux being greater than 20 and viscosity of the flux being greater than 40, such that the flux allows the chip to be effectively fixed to the lead frame and makes the solder bumps incapable of being easily wetted to the lead frame when the solder bumps are subjected to reflowing, so as to prevent over-collapsing of the solder bumps.

2. The flip-chip semiconductor package of claim 1, further comprising an encapsulant for encapsulating the semiconductor chip, the solder bumps and a portion of the lead frame.

3. The flip-chip semiconductor package of claim 1, wherein the lead frame comprises a plurality of leads for bonding the solder bumps formed on the chip.

4. The flip-chip semiconductor package of claim 3, wherein the lead frame further comprises a die pad for bonding the solder bumps formed on the chip, the die pad serving as an additional electrical connection contact for the semiconductor package.

5. The flip-chip semiconductor package of claim 1, wherein the solder bumps are made of a lead-rich material.

6. The flip-chip semiconductor package of claim 1, wherein the solder bumps are made of a lead-free material.

7. The flip-chip semiconductor package of claim 1, wherein the flux is formed on the surfaces of the solder bumps by one of dipping, printing and spraying.

8. A method for fabricating a flip-chip semiconductor package, comprising the steps of:
preparing at least one semiconductor chip having solder bumps formed on an active surface thereof, and forming a flux on surfaces of the solder bumps, wherein an acid number of the flux is greater than 20 and viscosity of the flux is greater than 40; and
electrically connecting the chip to a lead frame via the solder bumps by a reflowing process, wherein the flux allows the chip to be effectively fixed to the lead frame and makes the solder bumps incapable of being easily wetted to the lead frame during the reflowing process, so as to prevent over-collapsing of the solder bumps.

9. The method of claim 8, further comprises performing a molding process to form an encapsulant for encapsulating the semiconductor chip, the solder bumps and a portion of the lead frame.

10. The method of claim 8, wherein the lead frame comprises a plurality of leads for bonding the solder bumps formed on the chip.

11. The method of claim 10, wherein the lead frame further comprises a die pad for bonding the solder bumps formed on the chip, the die pad serving as an additional electrical connection contact for the semiconductor package.

12. The method of claim 8, wherein the solder bumps are made of a lead-rich material.

13. The method of claim 8, wherein the solder bumps are made of a lead-free material.

14. The method of claim 8, wherein the flux is formed on the surfaces of the solder bumps by one of dipping, printing and spraying.
